(19) United States
(12) Patent Application Publication
(10) Pub. No.: US 2025/0226352 A1
(43) Pub. Date: Jul. 10, 2025

(54) V-BONDING USING DOUBLE STACKED STAND-OFF-STITCH FOR IMPROVED RF PERFORMANCE

(71) Applicant: Lumentum Technology (UK) Limited, Northamptonshire (GB)

(72) Inventors: Angelito Pizarro LAO, Northampton (GB); Frank Kwasi FRIMPONG, Northampton (GB); Hauke Ingolf KREMER, Northampton (GB)

(21) Appl. No.: 18/589,055

(22) Filed: Feb. 27, 2024

Related U.S. Application Data
(60) Provisional application No. 63/619,031, filed on Jan. 9, 2024.

(51) Int. Cl. H01L 23/00; H01L 25/065

(52) U.S. Cl. CPC H01L 24/43; H01L 24/06; H01L 24/48; H01L 24/49; H01L 25/0655; H01L 2224/0612; H01L 2224/43; H01L 2224/48137; H01L 2224/49113; H01L 2224/49175; H01L 2924/1421

(57) ABSTRACT

A method of forming a wire bond assembly includes wire bonding a first end of a first bond wire to a first conductive bonding surface arranged on a first substrate to form a first conductive bond formation; wire bonding a second end of the first bond wire to a second conductive bonding surface arranged on a second substrate to form a second conductive bond formation, wherein the second substrate; forming a conductive structure on top of the first conductive bond formation; wire bonding a first end of a second bond wire to a top of the conductive structure to form a third conductive bond formation; and wire bonding a second end of the second bond wire to the second conductive bonding surface to form a fourth conductive bond formation, wherein the fourth conductive bond formation is laterally separated from the second conductive bond formation on the second conductive bonding surface.

### CROSS-REFERENCE TO RELATED APPLICATION

This patent application claims priority to U.S. Provisional Patent Application No. 63/619,031, filed on Jan. 9, 2024, and entitled “V-BONDING USING DOUBLE STACKED STAND-OFF-STITCH FOR IMPROVED RF PERFORMANCE.” The disclosure of the prior application is considered part of and is incorporated by reference into this patent application.

### TECHNICAL FIELD

The present disclosure relates generally to wire bonding and to forming v-bonds with a stacked configuration.

### BACKGROUND

Wire bonding is a method of making interconnections between an integrated circuit (IC) or other semiconductor device and its packaging during semiconductor device fabrication. Wire bonding can also be used to connect an IC to other electronics or to connect from one circuit substrate, such as a printed circuit board (PCB), to another circuit substrate. Ball bonding and wedge bonding are two types of wire bonding processes. Ball bonding may be performed by a ball bonding tool. Ball bonding may include, at a first end of a wire, a ball formation followed by a ball bond formation. Ball bonding may include, at a second end of the wire, a tail bond formation, which may include forming a stitch bond formation or a wedge bond formation to a ball by applying lateral ultrasonic vibration, downward pressure, and heat. Wedge bonding is another a type of wire bonding that relies on an application of lateral ultrasonic vibration and downward force to form conductive bonds (e.g., wedge bond formations) on conductive bonding surfaces located at both ends of a wire.

### SUMMARY

In some implementations, a method of forming a wire bond assembly includes wire bonding a first end of a first bond wire to a first conductive bonding surface arranged on a first substrate to form a first conductive bond formation; wire bonding a second end of the first bond wire to a second conductive bonding surface arranged on a second substrate to form a second conductive bond formation; forming a conductive structure on top of the first conductive bond formation; wire bonding a first end of a second bond wire to a top of the conductive structure to form a third conductive bond formation; and wire bonding a second end of the second bond wire to the second conductive bonding surface to form a fourth conductive bond formation, wherein the fourth conductive bond formation is laterally separated from the second conductive bond formation on the second conductive bonding surface.

In some implementations, a method of forming a wire bond assembly includes wire bonding a first end of a first bond wire to a first conductive bonding surface arranged on a first substrate to form a first conductive bond formation; wire bonding a second end of the first bond wire to a second conductive bonding surface arranged on a second substrate to form a second conductive bond formation; forming a first conductive structure on top of the first conductive bond formation; forming a second conductive structure on top of the second conductive bond formation; wire bonding a first end of a second bond wire to a top of the first conductive structure to form a third conductive bond formation; and wire bonding a second end of the second bond wire to a top of the second conductive structure to form a fourth conductive bond formation.

In some implementations, a wire bond assembly includes a first substrate comprising a first conductive bonding surface; a second substrate comprising a second conductive bonding surface; a first conductive bump arranged on the first conductive bonding surface; a first conductive ball arranged on the second conductive bonding surface, wherein the first conductive ball is bonded to a first end of a first bond wire; a second conductive ball arranged on the second conductive bonding surface, wherein the second conductive ball is bonded to a first end of a second bond wire, and wherein the second conductive ball is laterally separated from the first conductive ball on the second conductive bonding surface; and a second conductive bump, wherein a second end of the first bond wire is wire bonded to a top of the first conductive bump to form a first conductive bond formation, wherein the second conductive bump is arranged on the first conductive bond formation, and wherein a second end of the second bond wire is wire bonded to a top of the second conductive bump to form a second conductive bond formation.

### BRIEF DESCRIPTION OF THE DRAWINGS

FIGS. 1A-1D illustrate a method of forming a wire bond assembly according to one or more implementations.

FIGS. 2A-2D illustrate a method of forming a wire bond assembly according to one or more implementations.

FIGS. 3A-3D illustrate a method of forming a wire bond assembly according to one or more implementations.

FIGS. 4A-4C illustrate a method of forming a wire bond assembly according to one or more implementations.

FIGS. 5A-5D illustrate a method of forming a wire bond assembly according to one or more implementations.

FIGS. 6A-6C illustrate a method of forming a wire bond assembly according to one or more implementations.

FIGS. 7A-7D illustrate a method of forming a wire bond assembly according to one or more implementations.

FIGS. 8A-8D illustrate a method of forming a wire bond assembly according to one or more implementations.

FIGS. 9A-9C illustrate a method of forming a wire bond assembly according to one or more implementations.

FIGS. 10A-10C illustrate a method of forming a wire bond assembly according to one or more implementations.

### DETAILED DESCRIPTION

The following detailed description of example implementations refers to the accompanying drawings. The same reference numbers in different drawings may identify the same or similar elements.

Wire bonds should be made as short as possible to reduce wire bonding length and related parasitic inductance effects. When multiple wires are employed in a parallel configuration, larger diameter wire or ribbon bonds that have a wider cross section may be used to reduce inductance. However, a wider bond pad is needed to accommodate two wire bonds, a larger diameter wire, or a wider ribbon. For a radio frequency (RF) chip, it may be impractical to provide an RF bond pad that can accommodate two wires because of a lack of real estate or die area on the RF chip needed to accommodate wider bond pads. In addition, a wider bond pad on an RF receiver chip may increase parasitics (e.g., parasitic inductance), which may reduce a bandwidth of the RF receiver chip. Other types of chips or circuit substrates may face similar issues with smaller bond pads or other types of conductive bonding surfaces that cannot accommodate two parallel bond wires and/or wider bond wires that may be used to reduce parasitic inductance.

Some implementations described herein are directed to a method of implementing and sequencing wire bond interconnects between substrate structures with an objective of minimizing a parasitic inductive effect of the wire bond interconnects and minimizing capacitive effects of conductive bonding surfaces, such as bond pads. In RF receiver applications, improved optical receiver performance may be realized by increasing a bandwidth of an optical receiver by reducing parasitic inductance related to the wire bond interconnects.

The method may include using a pair of wire bond interconnects (e.g., bond wires) that start on a single conductive bonding surface and terminate in a V-configuration at a same termination point on a single conductive bonding surface. In other words, the pair of wire bond interconnects are vertically stacked (e.g., vertically bonded) on a conductive bonding surface of a first substrate structure (e.g., a first chip or a first circuit substrate), and are laterally bonded on a conductive bonding surface of a second substrate structure (e.g., a second chip or a second circuit substrate) to form the V-configuration. The pair of wire bond interconnects are arranged in a “V” to form an electrically parallel connection. As a result of arranging the two wire bond interconnects in the V-configuration, a lower inductance between two conductive bonding surfaces can be achieved. For example, V-bonds may provide lower inductance compared to 25 μm bonds. The lower inductance may be realized due to the two wire bond interconnects forming the electrically parallel connection. For example, an inductance of a V-bond wire assembly may be approximately 70% compared to a single wire of a same diameter. Thus, two wire bond interconnects arranged in the V-bond configuration may reduce parasitic inductance effects. In addition, vertically stacking the ends of the two wire bond interconnects on a same conductive bonding surface may enable the electrically parallel connection to be realized on smaller conductive bonding surfaces.

Using two wire bond interconnects with an electrically-equivalent parallel connection that are arranged in the V-bond configuration may be beneficial for connecting two substrate structures when using shorter wires, two side-by-side parallel wires, or larger wire sizes is not possible. Moreover, the V-bond configuration may increase an RF bandwidth of the connection. For example, a bonding technique for forming the V-bond configuration may be used to reduce a wirebond-induced peaking for optical receiver interconnects. For optical receivers, the reduction in wirebond-induced peaking may result in a more favorable/flat frequency response with enhanced bandwidth. However, the V-bond bonding technique is not limited to optical receivers and may be used in any application.

Some implementations described herein may be performed using a ball bonder tool, a wedge bonder tool, or a combination of a ball bonder tool and a wedge bonder tool.

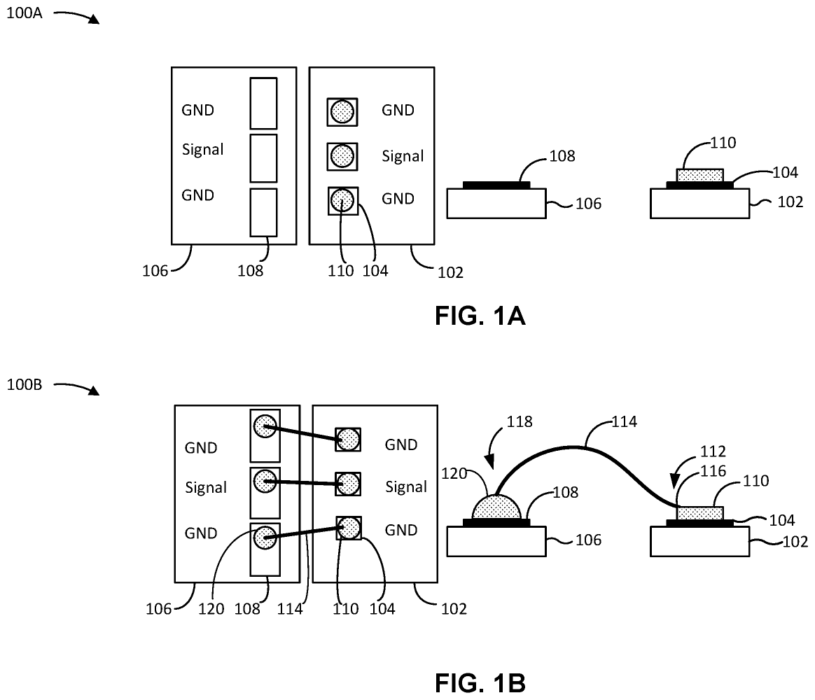

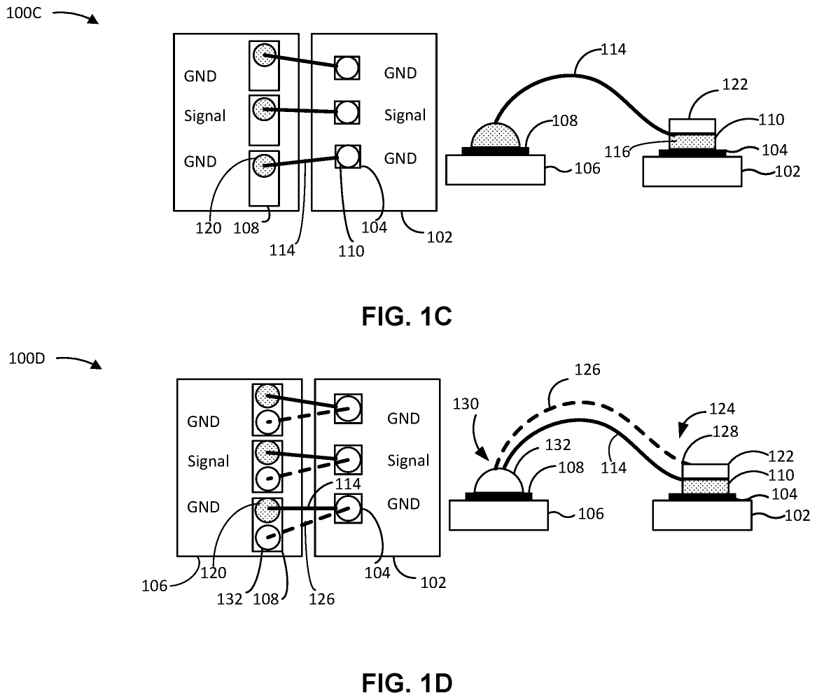

FIGS. 1A-1D illustrate a method of forming a wire bond assembly according to one or more implementations. FIG. 1A illustrates a top view and a side view of a first processing stage 100A of forming the wire bond assembly. The wire bond assembly includes forming wire bond connections between a first substrate 102 having a first conductive bonding surface 104 (e.g., a first bond pad or a first conductive contact) and a second substrate 106 having a second conductive bonding surface 108 (e.g., a second bond pad or a second conductive contact). The first substrate 102 may be a semiconductor substrate of a first semiconductor chip or may be a first circuit substrate. The second substrate 106 may be a semiconductor substrate of a second semiconductor chip or may be a second circuit substrate. In addition, the first substrate 102 and the second substrate 106 may have multiple conductive bonding surfaces for different types of electrical connections, such as power connections and signal connections. For example, power connections may include ground (GND) connections and/or positive supply connections, and signal connections may include electrical connections for transmitting RF signals, control signals, communication signals, and/or data signals.

The first processing stage 100A may include forming a first conductive bump 110 on top of the first conductive bonding surface 104.

FIG. 1B illustrates a top view and a side view of a second processing stage 100B of forming the wire bond assembly. The second processing stage 100B may include wire bonding a first end 112 of a first bond wire 114 to the first conductive bonding surface 104 arranged on the first substrate 102 to form a first conductive bond formation 116, such as a conductive wedge (i.e., wedge bond formation). The first conductive bond formation 116 may be formed on top of the first conductive bump 110. The second processing stage 100B may also include wire bonding a second end 118 of the first bond wire 114 to the second conductive bonding surface 108 arranged on the second substrate 106 to form a second conductive bond formation 120, such as a conductive ball (i.e., a ball bond formation). In some implementations, the second conductive bond formation 120 may be formed first as a first attachment such that the second end 118 of the first bond wire 114 is attached first, and then the first conductive bond formation 116 is formed as a second attachment after the second conductive bond formation 120 is formed such that the first end 112 of the first bond wire 114 is attached second.

FIG. 1C illustrates a top view and a side view of a third processing stage 100C of forming the wire bond assembly. The third processing stage 100C may include forming a conductive structure 122, such as a second conductive bump, on top of the first conductive bond formation 116. In other words, the conductive structure 122 may be formed on top of the conductive wedge that bonds the first end 112 of the first bond wire 114 to the top of the first conductive bump 110. Thus, the first conductive bump 110, the first conductive bond formation 116, and the conductive structure 122 may be arranged in a vertical stack.

FIG. 1D illustrates a top view and a side view of a fourth processing stage 100D of forming the wire bond assembly. The fourth processing stage 100D may include wire bonding a first end 124 of a second bond wire 126 to a top of the conductive structure 122 to form a third conductive bond formation 128. Thus, the third conductive bond formation 128 may be formed on top of the conductive structure 122 as a conductive wedge. As a result, the first conductive bump 110, the first conductive bond formation 116, the conductive structure 122 (e.g., the second conductive bump), and the third conductive bond formation 128 may be arranged in a vertical stack on the first conductive bonding surface 104.

The fourth processing stage 100D may also include wire bonding a second end 130 of the second bond wire 126 to the second conductive bonding surface 108 to form a fourth conductive bond formation 132, such as a conductive ball (i.e., a ball bond formation). In some implementations, the fourth conductive bond formation 132 may be formed first as a first attachment such that the second end 130 of the second bond wire 126 is attached first, and then the third conductive bond formation 128 is formed as a second attachment after the fourth conductive bond formation 132 is formed such that the first end 124 of the second bond wire 126 is attached second.

In addition, the fourth conductive bond formation 132 may be laterally separated from the second conductive bond formation 120 on the second conductive bonding surface 108. For example, the second conductive bond formation 120 and the fourth conductive bond formation 132 may be formed directly on the second conductive bonding surface 108, and may be separated from each other in a lateral dimension. Thus, the first bond wire 114 and the second bond wire 126 may be coupled to the first conductive bonding surface 104 and the second conductive bonding surface 108 in a V-configuration to form an electrically parallel connection between the first conductive bonding surface 104 and the second conductive bonding surface 108.

The first conductive bond formation 116 may be a first conductive wedge, the second conductive bond formation 120 may be a first conductive ball, the third conductive bond formation 128 may be a second conductive wedge, and the fourth conductive bond formation 132 may be a second conductive ball. Moreover, the first conductive bump 110 may be formed directly on the first conductive bonding surface 104, the first conductive bond formation 116 may be formed directly on the first conductive bump 110, the conductive structure 122 (e.g., the second conductive bump) may be formed directly on the first conductive bond formation 116, and the third conductive bond formation 128 may be formed directly on the conductive structure 122.

As indicated above, FIGS. 1A-1D are provided as examples. Other examples may differ from what is described with regard to FIGS. 1A-1D.

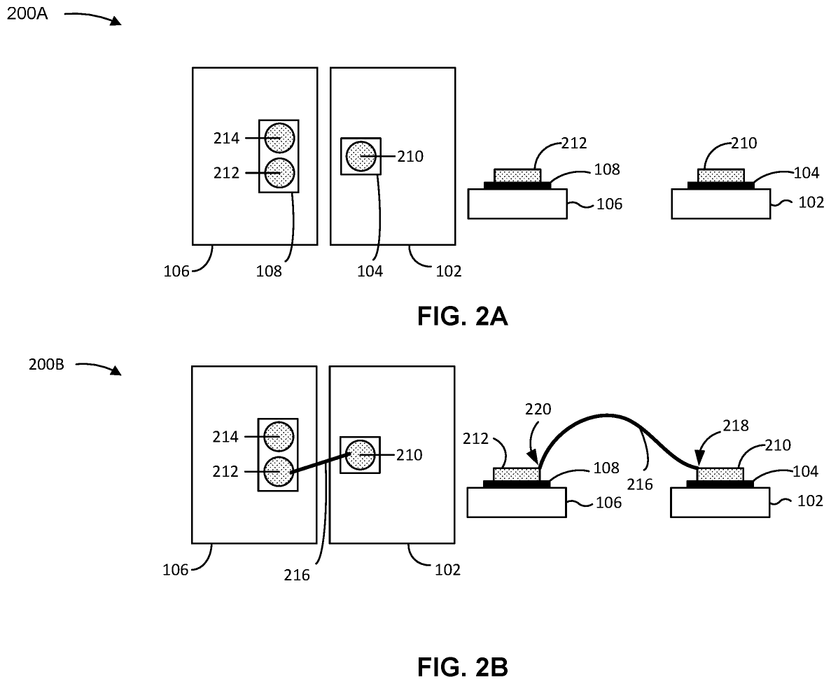

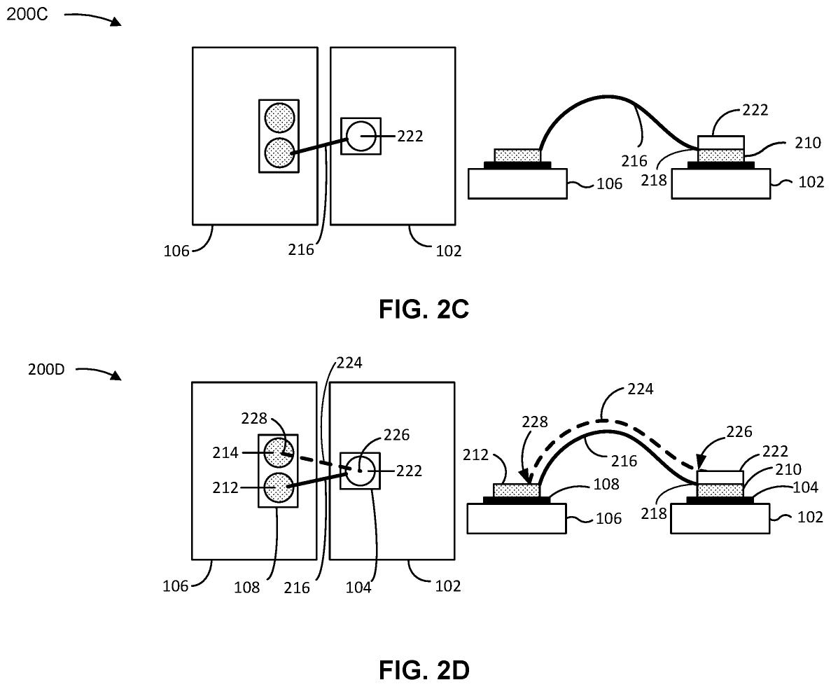

FIGS. 2A-2D illustrate a method of forming a wire bond assembly according to one or more implementations. FIG. 2A illustrates a top view and a side view of a first processing stage 200A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 200A may include forming a first conductive bump 210 on top of the first conductive bonding surface 104. The first processing stage 200A may also include forming a second conductive bump 212 and a third conductive bump 214 on top of the second conductive bonding surface 108. The second conductive bump 212 and the third conductive bump 214 may be laterally separated from each other on the second conductive bonding surface 108.

FIG. 2B illustrates a top view and a side view of a second processing stage 200B of forming the wire bond assembly. The second processing stage 200B may include wire bonding a first end of a first bond wire 216 to the first conductive bump 210 to form a first conductive bond formation 218 (e.g. a conductive wedge). The second processing stage 200B may include wire bonding a second end of the first bond wire 216 to the second conductive bump 212 to form a second conductive bond formation 220 (e.g., a conductive wedge). Thus, the second processing stage 200B includes wire bonding the first end of the first bond wire 216 to the first conductive bonding surface 104, and wire bonding the second end of the first bond wire 216 to the second conductive bonding surface 108.

FIG. 2C illustrates a top view and a side view of a third processing stage 200C of forming the wire bond assembly. The third processing stage 200C may include forming a fourth conductive bump 222 on top of the first conductive bond formation 218.

FIG. 2D illustrates a top view and a side view of a fourth processing stage 200D of forming the wire bond assembly. The fourth processing stage 200D may include wire bonding a first end of a second bond wire 224 to a top of the fourth conductive bump 222 to form a third conductive bond formation 226 (e.g., a conductive wedge). The fourth processing stage 200D may also include wire bonding a second end of the second bond wire 224 to the third conductive bump 214 to form a fourth conductive bond formation 228 (e.g., a conductive wedge). The fourth conductive bond formation 228 is laterally separated from the second conductive bond formation 220 on the second conductive bonding surface 108. Thus, the first bond wire 216 and the second bond wire 224 may be coupled to the first conductive bonding surface 104 and the second conductive bonding surface 108 in a V-configuration to form an electrically parallel connection between the first conductive bonding surface 104 and the second conductive bonding surface 108.

As indicated above, FIGS. 2A-2D are provided as examples. Other examples may differ from what is described with regard to FIGS. 2A-2D.

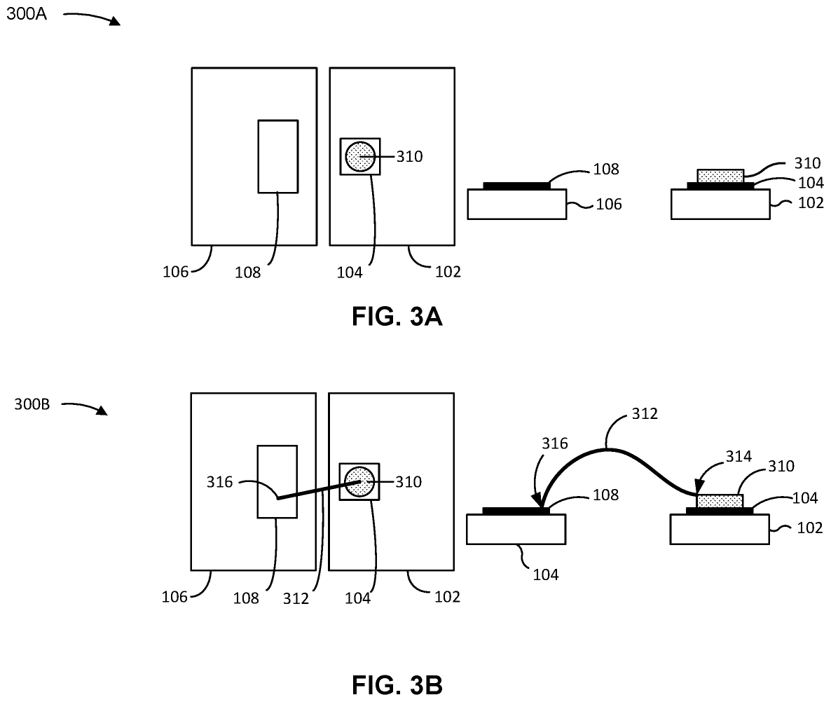

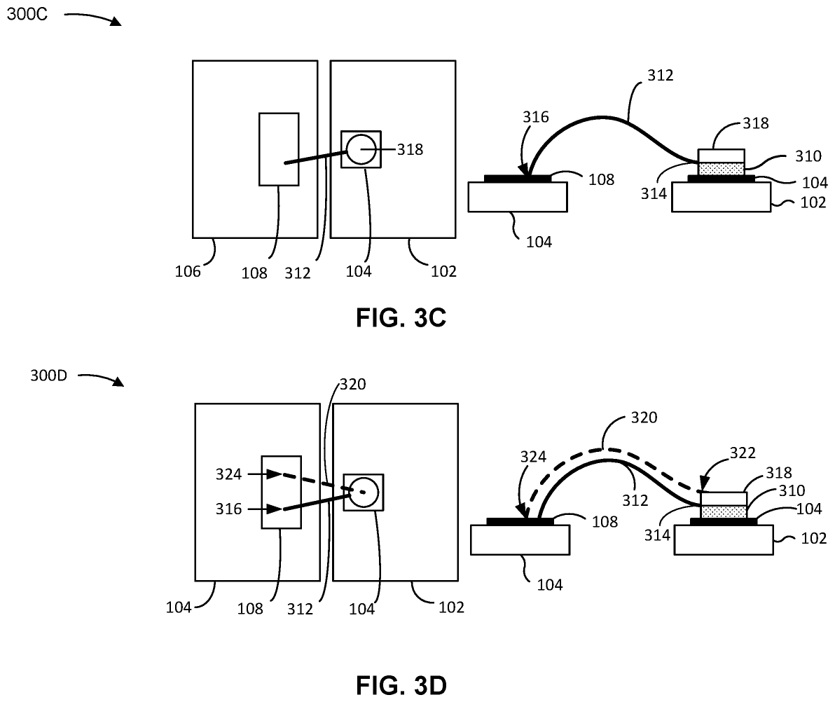

FIGS. 3A-3D illustrate a method of forming a wire bond assembly according to one or more implementations. FIG. 3A illustrates a top view and a side view of a first processing stage 300A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 300A may include forming a first conductive bump 310 on top of the first conductive bonding surface 104.

FIG. 3B illustrates a top view and a side view of a second processing stage 300B of forming the wire bond assembly. The second processing stage 300B may include wire bonding a first end of a first bond wire 312 to the first conductive bump 310 to form a first conductive bond formation 314 (e.g. a conductive wedge). The second processing stage 300B may also include wire bonding a second end of the first bond wire 312 to the second conductive bonding surface 108 to form a second conductive bond formation 316 (e.g., a conductive wedge). Thus, the second processing stage 300B includes wire bonding the first end of the first bond wire 312 to the first conductive bonding surface 104, and wire bonding the second end of the first bond wire 312 to the second conductive bonding surface 108.

FIG. 3C illustrates a top view and a side view of a third processing stage 300C of forming the wire bond assembly. The third processing stage 300C may include forming a second conductive bump 318 on top of the first conductive bond formation 314.

FIG. 3D illustrates a top view and a side view of a fourth processing stage 300D of forming the wire bond assembly. The fourth processing stage 300D may include wire bonding a first end of a second bond wire 320 to a top of the second conductive bump 318 to form a third conductive bond formation 322 (e.g., a conductive wedge). The fourth processing stage 300D may also include wire bonding a second end of the second bond wire 320 to the second conductive bonding surface 108 to form a fourth conductive bond formation 324 (e.g., a conductive wedge). The fourth conductive bond formation 324 is laterally separated from the second conductive bond formation 316 on the second conductive bonding surface 108. Thus, the first bond wire 312 and the second bond wire 320 may be coupled to the first conductive bonding surface 104 and the second conductive bonding surface 108 in a V-configuration to form an electrically parallel connection between the first conductive bonding surface 104 and the second conductive bonding surface 108.

As indicated above, FIGS. 3A-3D are provided as examples. Other examples may differ from what is described with regard to FIGS. 3A-3D.

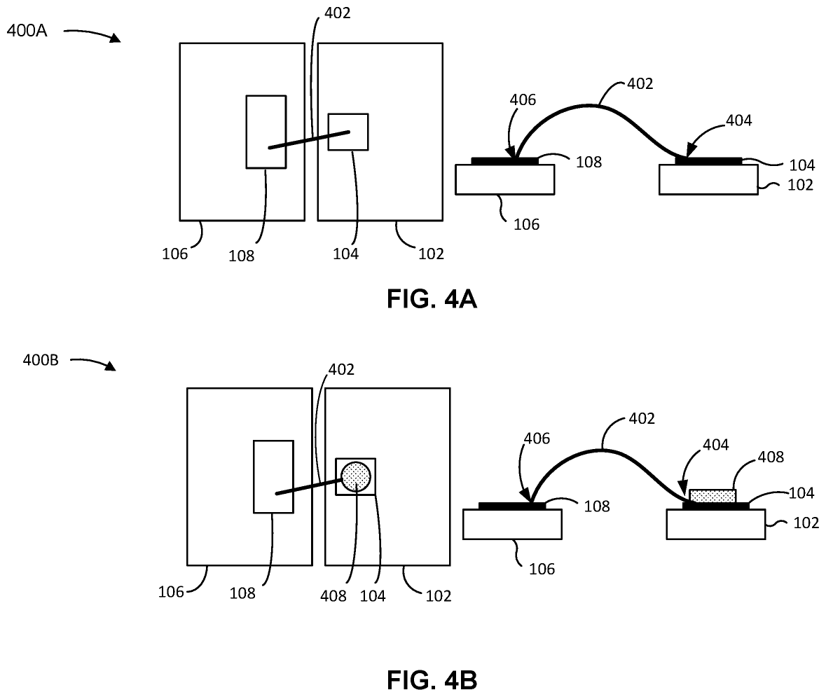

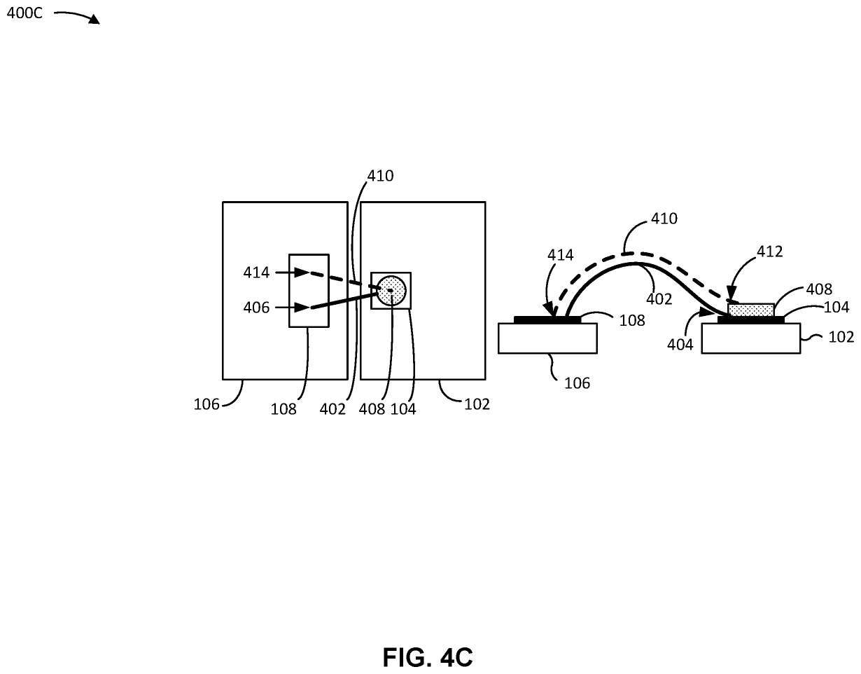

FIGS. 4A-4C illustrate a method of forming a wire bond assembly according to one or more implementations. FIG. 4A illustrates a top view and a side view of a first processing stage 400A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 400A may include wire bonding a first end of a first bond wire 402 to the first conductive bonding surface 104 to form a first conductive bond formation 404 (e.g. a conductive wedge). Thus, the first end of a first bond wire 402 may be bonded directly to the first conductive bonding surface 104. The first processing stage 400A may also include wire bonding a second end of the first bond wire 402 to the second conductive bonding surface 108 to form a second conductive bond formation 406 (e.g., a conductive wedge). Thus, the second end of the first bond wire 402 may be bonded directly to the second conductive bonding surface 108.

FIG. 4B illustrates a top view and a side view of a second processing stage 400B of forming the wire bond assembly. The second processing stage 400B may include forming a first conductive bump 408 on top of the first conductive bond formation 404.

FIG. 4C illustrates a top view and a side view of a third processing stage 400C of forming the wire bond assembly. The third processing stage 400C may include wire bonding a first end of a second bond wire 410 to a top of the first conductive bump 408 to form a third conductive bond formation 412 (e.g., a conductive wedge). The third processing stage 400C may also include wire bonding a second end of the second bond wire 410 to the second conductive bonding surface 108 to form a fourth conductive bond formation 414 (e.g., a conductive wedge). The fourth conductive bond formation 414 is laterally separated from the second conductive bond formation 406 on the second conductive bonding surface 108. Thus, the first bond wire 402 and the second bond wire 410 may be coupled to the first conductive bonding surface 104 and the second conductive bonding surface 108 in a V-configuration to form an electrically parallel connection between the first conductive bonding surface 104 and the second conductive bonding surface 108.

As indicated above, FIGS. 4A-4C are provided as examples. Other examples may differ from what is described with regard to FIGS. 4A-4C.

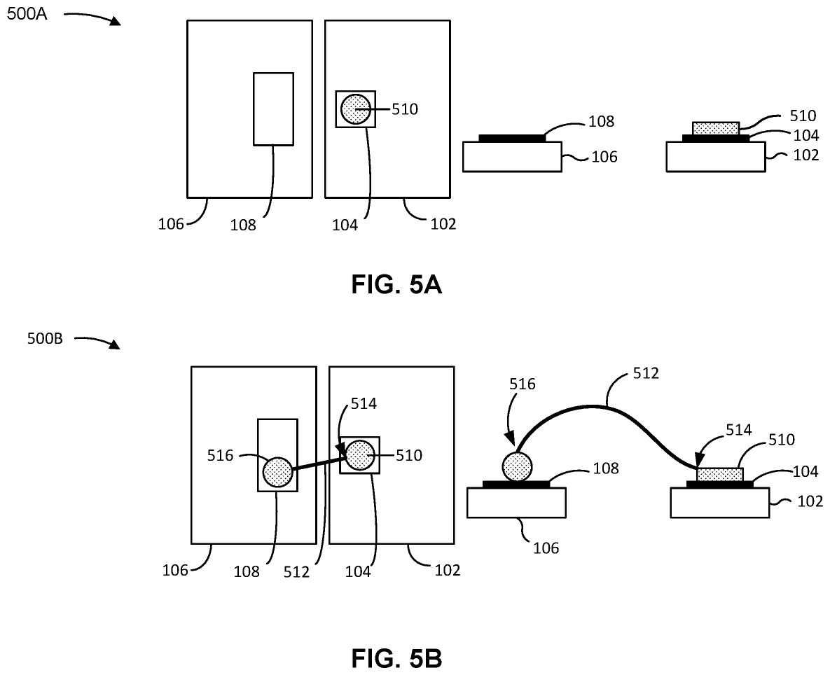

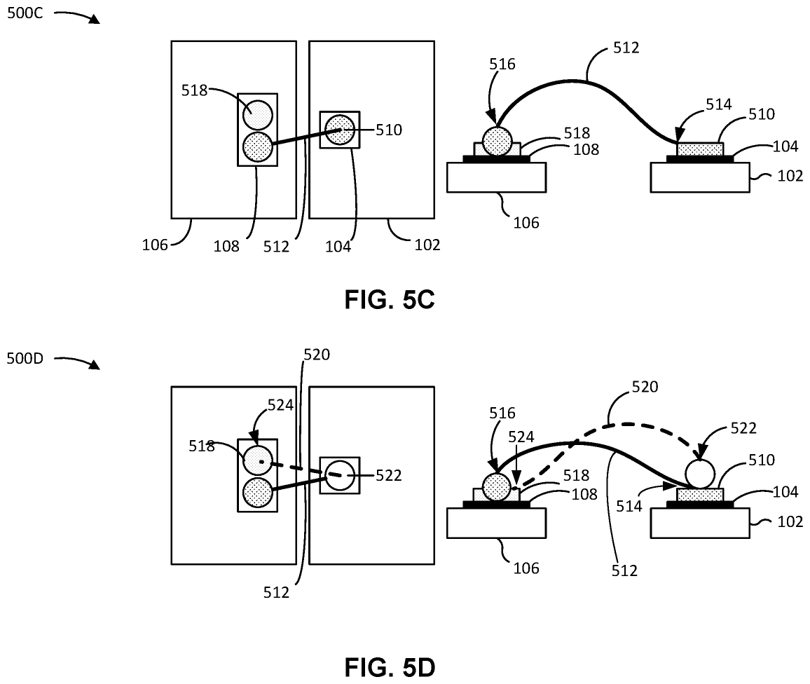

FIGS. 5A-5D illustrate a method of forming a wire bond assembly according to one or more implementations. FIG. 5A illustrates a top view and a side view of a first processing stage 500A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 500A may include forming a first conductive bump 510 on top of the first conductive bonding surface 104.

FIG. 5B illustrates a top view and a side view of a second processing stage 500B of forming the wire bond assembly. The second processing stage 500B may include wire bonding a first end of a first bond wire 512 to the first conductive bonding surface 104 arranged on the first substrate 102 to form a first conductive bond formation 514, such as a conductive wedge (i.e., wedge bond formation). The first conductive bond formation 514 may be formed on top of the first conductive bump 510. The second processing stage 500B may also include wire bonding a second end of the first bond wire 512 to the second conductive bonding surface 108 arranged on the second substrate 106 to form a second conductive bond formation 516, such as a conductive ball (i.e., a ball bond formation). In some implementations, the second conductive bond formation 516 may be formed first as a first attachment such that the second end of the first bond wire 512 is attached first, and then the first conductive bond formation 514 is formed as a second attachment after the second conductive bond formation 516 is formed such that the first end of the first bond wire 512 is attached second.

FIG. 5C illustrates a top view and a side view of a third processing stage 500C of forming the wire bond assembly. The third processing stage 500C may include forming a second conductive bump 518 on top of the second conductive bonding surface 108. The second conductive bump 518 may be laterally separated from the second conductive bond formation 516 on the second conductive bonding surface 108.

FIG. 5D illustrates a top view and a side view of a fourth processing stage 500D of forming the wire bond assembly. The fourth processing stage 500D may include wire bonding a first end of a second bond wire 520 to a top of the first conductive bump 510 to form a third conductive bond formation 522 such as a conductive ball (i.e., a ball bond formation). Thus, the third conductive bond formation 522 may be a conductive structure formed on top of the first conductive bump 510. As a result, the first conductive bump 510, the first conductive bond formation 514, and the third conductive bond formation 522 may be arranged in a vertical stack on the first conductive bonding surface 104.

The fourth processing stage 500D may also include wire bonding a second end of the second bond wire 520 to the second conductive bump 518 to form a fourth conductive bond formation 524, such as a conductive wedge (i.e., a wedge bond formation). Thus, the first bond wire 512 and the second bond wire 520 may be coupled to the first conductive bonding surface 104 and the second conductive bonding surface 108 in a V-configuration to form an electrically parallel connection between the first conductive bonding surface 104 and the second conductive bonding surface 108.

As indicated above, FIGS. 5A-5D are provided as examples. Other examples may differ from what is described with regard to FIGS. 5A-5D.

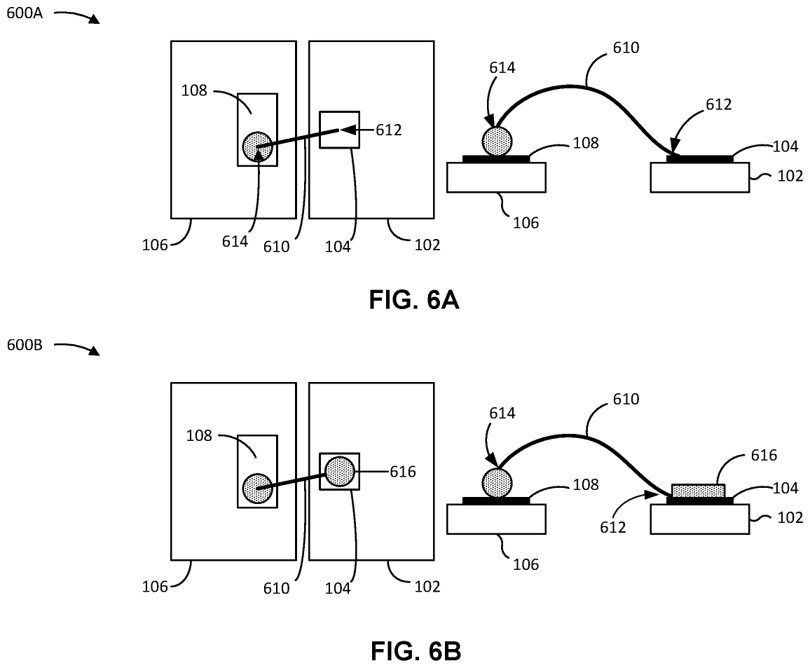

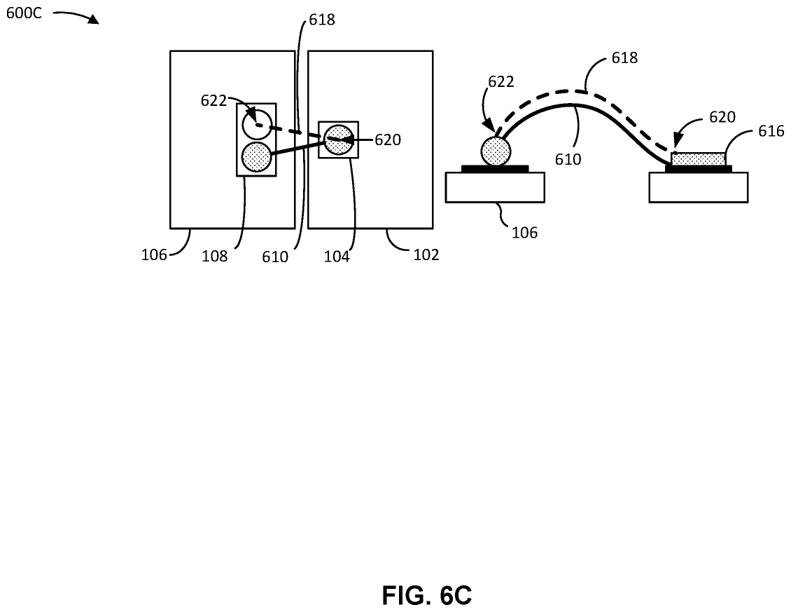

FIGS. 6A-6C illustrate a method of forming a wire bond assembly according to one or more implementations. FIG. 6A illustrates a top view and a side view of a first processing stage 600A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 600A may include wire bonding a first end of a first bond wire 610 to the first conductive bonding surface 104 to form a first conductive bond formation 612 (e.g. a conductive wedge). Thus, the first end of a first bond wire 610 may be bonded directly to the first conductive bonding surface 104. The first processing stage 600A may also include wire bonding a second end of the first bond wire 610 to the second conductive bonding surface 108 to form a second conductive bond formation 614 (e.g., a conductive ball). Thus, the second end of the first bond wire 610 may be bonded directly to the second conductive bonding surface 108. In some implementations, the second conductive bond formation 614 may be formed first as a first attachment such that the second end of the first bond wire 610 is attached first, and then the first conductive bond formation 612 is formed as a second attachment after the second conductive bond formation 614 is formed such that the first end of the first bond wire 610 is attached second.

FIG. 6B illustrates a top view and a side view of a second processing stage 600B of forming the wire bond assembly. The second processing stage 600B may include forming a first conductive bump 616 on top of the first conductive bond formation 612.

FIG. 6C illustrates a top view and a side view of a third processing stage 600C of forming the wire bond assembly. The third processing stage 600C may include wire bonding a first end of a second bond wire 618 to a top of the first conductive bump 616 to form a third conductive bond formation 620 (e.g., a conductive wedge). The third processing stage 600C may also include wire bonding a second end of the second bond wire 618 to the second conductive bonding surface 108 to form a fourth conductive bond formation 622 (e.g., a conductive ball). In some implementations, the fourth conductive bond formation 622 may be formed first as a first attachment such that the second end of the second bond wire 618 is attached first, and then the third conductive bond formation 620 is formed as a second attachment after the fourth conductive bond formation 622 is formed such that the first end of the second bond wire 618 is attached second.

The fourth conductive bond formation 622 is laterally separated from the second conductive bond formation 614 on the second conductive bonding surface 108. Thus, the first bond wire 610 and the second bond wire 618 may be coupled to the first conductive bonding surface 104 and the second conductive bonding surface 108 in a V-configuration to form an electrically parallel connection between the first conductive bonding surface 104 and the second conductive bonding surface 108.

As indicated above, FIGS. 6A-6C are provided as examples. Other examples may differ from what is described with regard to FIGS. 6A-6C.

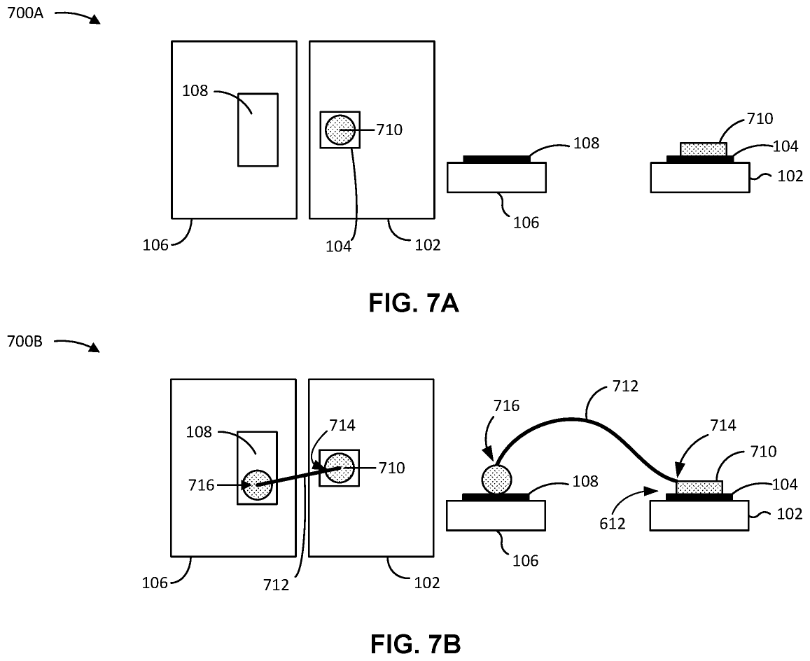

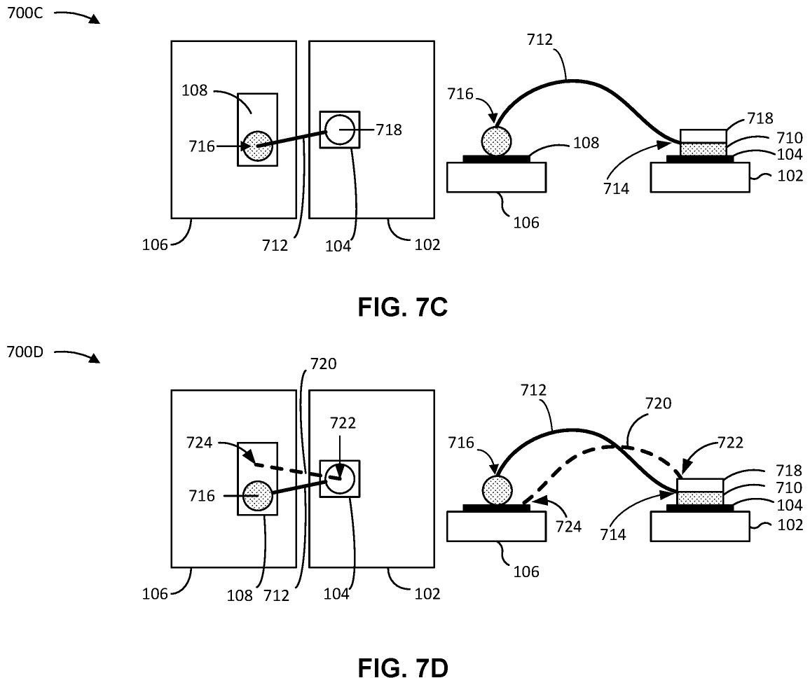

FIGS. 7A-7D illustrate a method of forming a wire bond assembly according to one or more implementations. FIG. 7A illustrates a top view and a side view of a first processing stage 700A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 700A may include forming a first conductive bump 710 on top of the first conductive bonding surface 104.

FIG. 7B illustrates a top view and a side view of a second processing stage 700B of forming the wire bond assembly. The second processing stage 700B may include wire bonding a first end of a first bond wire 712 to the first conductive bonding surface 104 arranged on the first substrate 102 to form a first conductive bond formation 714, such as a conductive wedge (i.e., wedge bond formation). The first conductive bond formation 714 may be formed on top of the first conductive bump 710. The second processing stage 700B may also include wire bonding a second end of the first bond wire 712 to the second conductive bonding surface 108 arranged on the second substrate 106 to form a second conductive bond formation 716, such as a conductive ball (i.e., a ball bond formation). In some implementations, the second conductive bond formation 716 may be formed first as a first attachment such that the second end of the first bond wire 712 is attached first, and then the first conductive bond formation 714 is formed as a second attachment after the second conductive bond formation 716 is formed such that the first end of the first bond wire 712 is attached second.

FIG. 7C illustrates a top view and a side view of a third processing stage 700C of forming the wire bond assembly. The third processing stage 700C may include forming a second conductive bump 718 on top of the first conductive bond formation 714.

FIG. 7D illustrates a top view and a side view of a fourth processing stage 700D of forming the wire bond assembly. The fourth processing stage 700D may include wire bonding a first end of a second bond wire 720 to a top of the second conductive bump 718 to form a third conductive bond formation 722 (e.g., a conductive wedge). The fourth processing stage 300D may also include wire bonding a second end of the second bond wire 720 to the second conductive bonding surface 108 to form a fourth conductive bond formation 724 (e.g., a conductive wedge). The fourth conductive bond formation 724 is laterally separated from the second conductive bond formation 716 on the second conductive bonding surface 108. Thus, the first bond wire 712 and the second bond wire 720 may be coupled to the first conductive bonding surface 104 and the second conductive bonding surface 108 in a V-configuration to form an electrically parallel connection between the first conductive bonding surface 104 and the second conductive bonding surface 108.

As indicated above, FIGS. 7A-7D are provided as examples. Other examples may differ from what is described with regard to FIGS. 7A-7D.

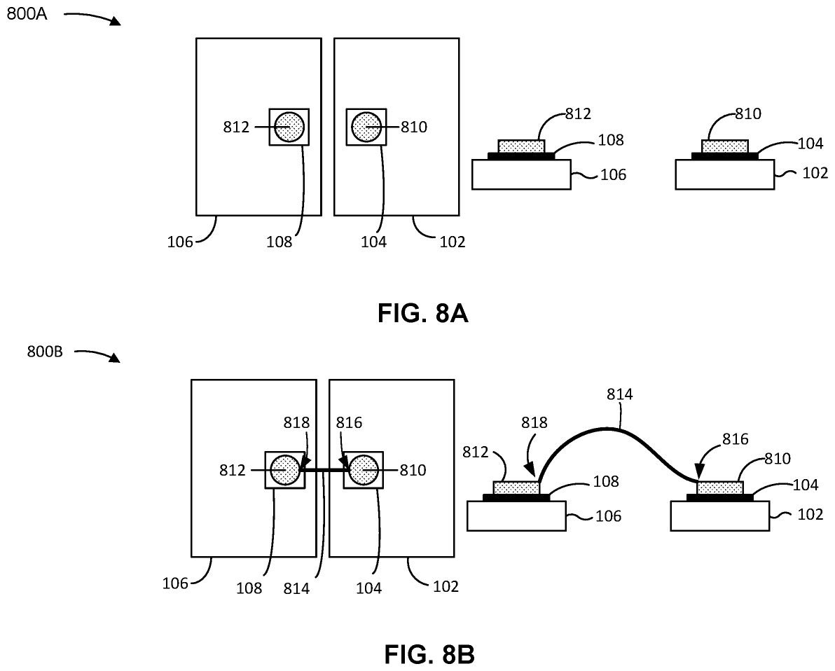

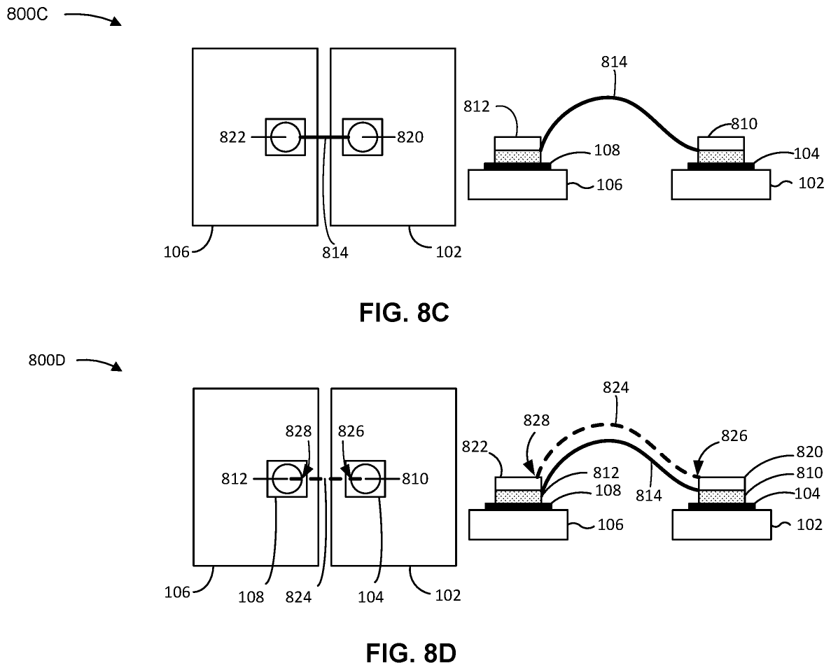

FIGS. 8A-8D illustrate a method of forming a wire bond assembly according to one or more implementations. FIG. 8A illustrates a top view and a side view of a first processing stage 800A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 800A may include forming a first conductive bump 810 on top of the first conductive bonding surface 104. The first processing stage 800A may also include forming a second conductive bump 812 on top of the second conductive bonding surface 108.

FIG. 8B illustrates a top view and a side view of a second processing stage 800B of forming the wire bond assembly. The second processing stage 800B may include wire bonding a first end of a first bond wire 814 to the first conductive bump 810 to form a first conductive bond formation 816 (e.g. a conductive wedge). The second processing stage 800B may also include wire bonding a second end of the first bond wire 814 to the second conductive bump 812 to form a second conductive bond formation 818 (e.g., a conductive wedge). Thus, the second processing stage 800B includes wire bonding the first end of the first bond wire 814 to the first conductive bonding surface 104, and wire bonding the second end of the first bond wire 814 to the second conductive bonding surface 108.

FIG. 8C illustrates a top view and a side view of a third processing stage 800C of forming the wire bond assembly. The third processing stage 800C may include forming a third conductive bump 820 on top of the first conductive bond formation 816, and forming a fourth conductive bump 822 on top of the second conductive bond formation 818.

FIG. 8D illustrates a top view and a side view of a fourth processing stage 800D of forming the wire bond assembly. The fourth processing stage 800D may include wire bonding a first end of a second bond wire 824 to a top of the third conductive bump 820 to form a third conductive bond formation 826 (e.g., a conductive wedge). The fourth processing stage 800D may also include wire bonding a second end of the second bond wire 824 to a top of the fourth conductive bump 822 to form a fourth conductive bond formation 828 (e.g., a conductive wedge).

As a result, the first conductive bump 810, the first conductive bond formation 816, the third conductive bump 820, and the third conductive bond formation 826 may be arranged in a vertical stack on the first conductive bonding surface 104. Additionally, the second conductive bump 812, the second conductive bond formation 818, the fourth conductive bump 822, and the fourth conductive bond formation 828 may be arranged in a vertical stack on the second conductive bonding surface 108. Thus, the first bond wire 814 and the second bond wire 824 may be coupled to the first conductive bonding surface 104 and the second conductive bonding surface 108 in parallel to form an electrically parallel connection between the first conductive bonding surface 104 and the second conductive bonding surface 108.

As indicated above, FIGS. 8A-8D are provided as examples. Other examples may differ from what is described with regard to FIGS. 8A-8D.

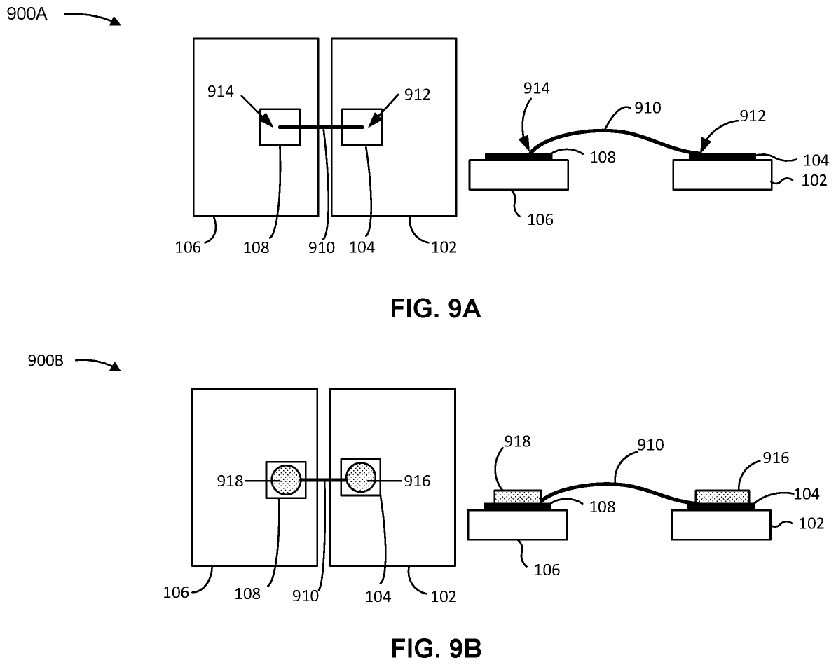

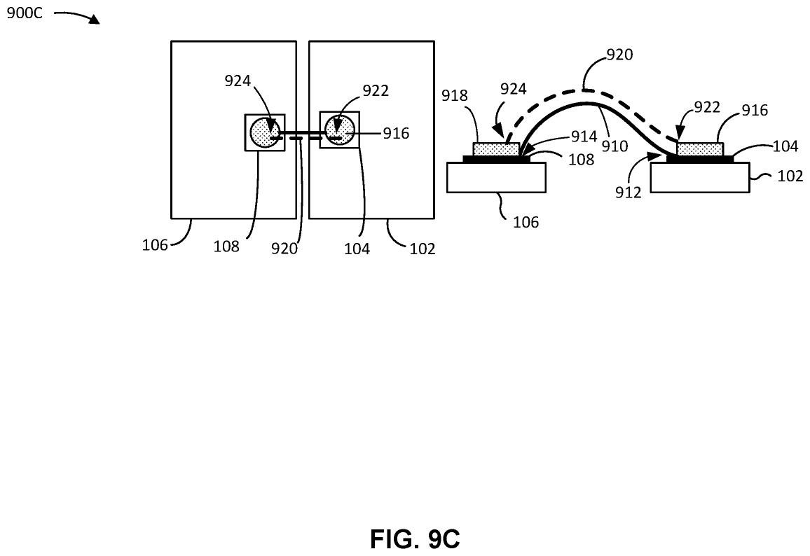

FIGS. 9A-9C illustrate a method of forming a wire bond assembly according to one or more implementations. FIG. 9A illustrates a top view and a side view of a first processing stage 900A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 900A may include wire bonding a first end of a first bond wire 910 to the first conductive bonding surface 104 to form a first conductive bond formation 912 (e.g. a conductive wedge). The second processing stage 900B may also include wire bonding a second end of the first bond wire 910 to the second conductive bonding surface 108 to form a second conductive bond formation 914 (e.g., a conductive wedge).

FIG. 9B illustrates a top view and a side view of a second processing stage 900B of forming the wire bond assembly. The second processing stage 900B may include forming a first conductive bump 916 on top of the first conductive bond formation 912, and forming a second conductive bump 918 on top of the second conductive bond formation 914.

FIG. 9C illustrates a top view and a side view of a third processing stage 900C of forming the wire bond assembly. The third processing stage 900C may include wire bonding a first end of a second bond wire 920 to a top of the first conductive bump 916 to form a third conductive bond formation 922 (e.g., a conductive wedge). The third processing stage 900C may also include wire bonding a second end of the second bond wire 920 to a top of the second conductive bump 918 to form a fourth conductive bond formation 924 (e.g., a conductive wedge).

As a result, the first conductive bond formation 912, the first conductive bump 916, and the third conductive bond formation 922 may be arranged in a vertical stack on the first conductive bonding surface 104. Additionally, the second conductive bond formation 914, the second conductive bump 918, and the fourth conductive bond formation 924 may be arranged in a vertical stack on the second conductive bonding surface 108. Thus, the first bond wire 910 and the second bond wire 920 may be coupled to the first conductive bonding surface 104 and the second conductive bonding surface 108 in parallel to form an electrically parallel connection between the first conductive bonding surface 104 and the second conductive bonding surface 108.

As indicated above, FIGS. 9A-9C are provided as examples. Other examples may differ from what is described with regard to FIGS. 9A-9C.

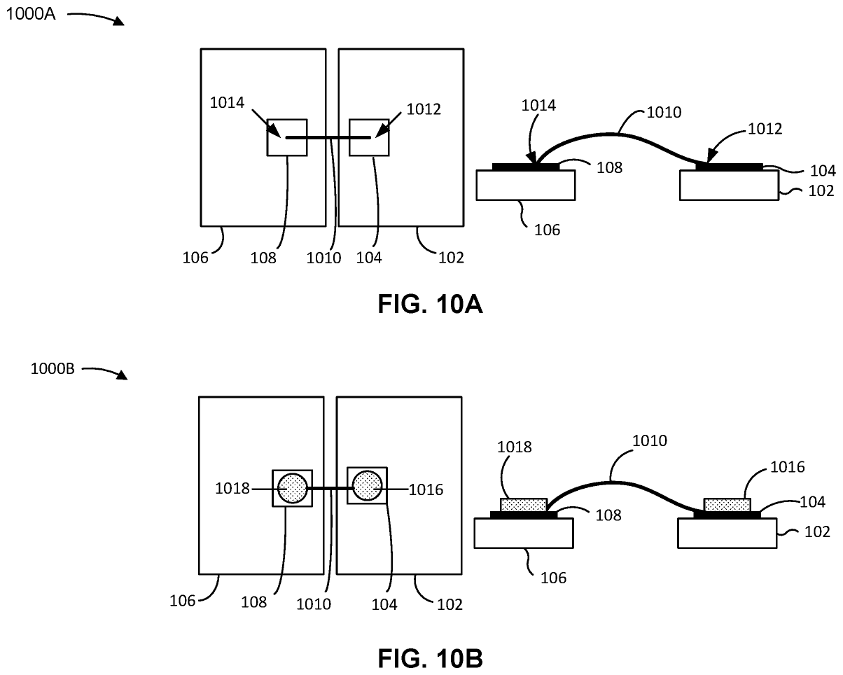

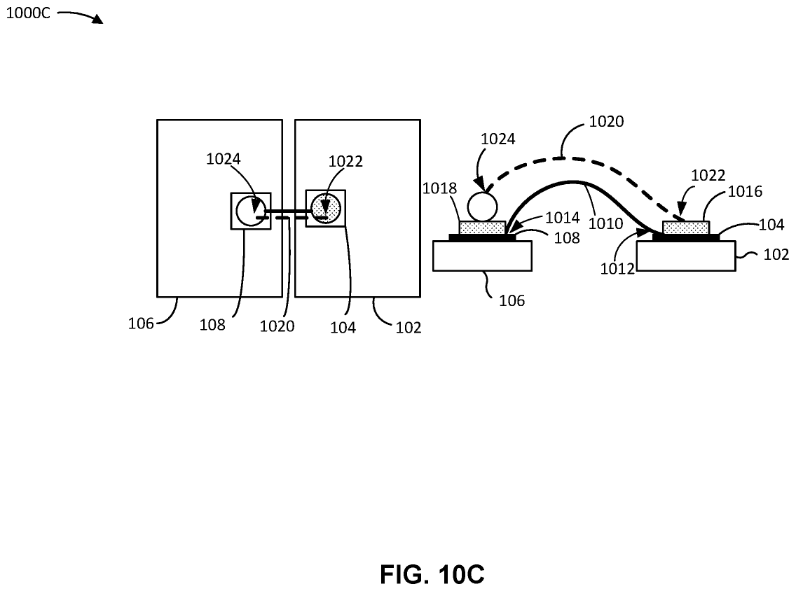

FIGS. 10A-10C illustrate a method of forming a wire bond assembly according to one or more implementations. FIG. 10A illustrates a top view and a side view of a first processing stage 1000A of forming the wire bond assembly. Similar to the wire bond assembly described in connection with FIGS. 1A-1D, the method of forming the wire bond assembly includes forming wire bond connections between the first substrate 102 having the first conductive bonding surface 104 (e.g., a first bond pad or a first conductive contact) and the second substrate 106 having the second conductive bonding surface 108 (e.g., a second bond pad or a second conductive contact).

The first processing stage 1000A may include wire bonding a first end of a first bond wire 1010 to the first conductive bonding surface 104 to form a first conductive bond formation 1012 (e.g. a conductive wedge). The second processing stage 1000B may also include wire bonding a second end of the first bond wire 1010 to the second conductive bonding surface 108 to form a second conductive bond formation 1014 (e.g., a conductive wedge).

FIG. 10B illustrates a top view and a side view of a second processing stage 1000B of forming the wire bond assembly. The second processing stage 1000B may include forming a first conductive bump 1016 on top of the first conductive bond formation 1012, and forming a second conductive bump 1018 on top of the second conductive bond formation 1014.

FIG. 10C illustrates a top view and a side view of a third processing stage 1000C of forming the wire bond assembly. The third processing stage 1000C may include wire bonding a first end of a second bond wire 1020 to a top of the first conductive bump 1016 to form a third conductive bond formation 1022 (e.g., a conductive wedge). The third processing stage 1000C may also include wire bonding a second end of the second bond wire 1020 to a top of the second conductive bump 1018 to form a fourth conductive bond formation 1024 (e.g., a conductive ball). In some implementations, the fourth conductive bond formation 1024 may be formed first as a first attachment such that the second end of the second bond wire 1020 is attached first, and then the third conductive bond formation 1022 is formed as a second attachment after the fourth conductive bond formation 1024 is formed such that the first end of the second bond wire 1020 is attached second.

As a result, the first conductive bond formation 1012, the first conductive bump 1016, and the third conductive bond formation 1022 may be arranged in a vertical stack on the first conductive bonding surface 104. Additionally, the second conductive bond formation 1014, the second conductive bump 1018, and the fourth conductive bond formation 1024 may be arranged in a vertical stack on the second conductive bonding surface 108. Thus, the first bond wire 910 and the second bond wire 920 may be coupled to the first conductive bonding surface 104 and the second conductive bonding surface 108 in parallel to form an electrically parallel connection between the first conductive bonding surface 104 and the second conductive bonding surface 108.

As indicated above, FIGS. 10A-10C are provided as examples. Other examples may differ from what is described with regard to FIGS. 10A-10C.

The following provides an overview of some Aspects of the present disclosure:

Aspect 1: A method of forming a wire bond assembly, the method comprising: wire bonding a first end of a first bond wire to a first conductive bonding surface arranged on a first substrate to form a first conductive bond formation; wire bonding a second end of the first bond wire to a second conductive bonding surface arranged on a second substrate to form a second conductive bond formation; forming a conductive structure on top of the first conductive bond formation; wire bonding a first end of a second bond wire to a top of the conductive structure to form a third conductive bond formation; and wire bonding a second end of the second bond wire to the second conductive bonding surface to form a fourth conductive bond formation, wherein the fourth conductive bond formation is laterally separated from the second conductive bond formation on the second conductive bonding surface.

Aspect 2: The method of Aspect 1, wherein the first bond wire and the second bond wire are coupled to the first conductive bonding surface and the second conductive bonding surface in a v-configuration to form an electrically parallel connection between the first conductive bonding surface and the second conductive bonding surface.

Aspect 3: The method of any of Aspects 1-2, wherein the first conductive bond formation, the conductive structure, and the third conductive bond formation form a vertical stack on the first conductive bonding surface.

Aspect 4: The method of any of Aspects 1-3, wherein the first conductive bond formation is a first conductive wedge, wherein the second conductive bond formation is a first conductive ball, wherein the third conductive bond formation is a second conductive wedge, and wherein the fourth conductive bond formation is a second conductive ball.

Aspect 5: The method of any of Aspects 1-4, further comprising: forming a first conductive bump on top of the first conductive bonding surface, wherein the conductive structure is a second conductive bump, and wherein the first conductive bond formation is formed on top of the first conductive bump.

Aspect 6: The method of Aspect 5, wherein the first conductive bump is formed directly on the first conductive bonding surface, the first conductive bond formation is formed directly on the first conductive bump, the second conductive bump is formed directly on the first conductive bond formation, and the third conductive bond formation is formed directly on the second conductive bump.

Aspect 7: The method of Aspect 5, further comprising: forming a third conductive bump on top of the second conductive bonding surface; and forming a fourth conductive bump on top of the second conductive bonding surface, wherein the fourth conductive bump is laterally separated from the third conductive bump on the second conductive bonding surface, wherein the second conductive bond formation is formed on top of the third conductive bump, and wherein the fourth conductive bond formation is formed on top of the fourth conductive bump.

Aspect 8: The method of Aspect 7, wherein the first conductive bond formation is a first conductive wedge, wherein the second conductive bond formation is a second conductive wedge, wherein the third conductive bond formation is a third conductive wedge, and wherein the fourth conductive bond formation is a fourth conductive wedge.

Aspect 9: The method of any of Aspects 1-8, further comprising: forming a first conductive bump on top of the first conductive bonding surface, wherein the conductive structure is a second conductive bump, wherein the first conductive bond formation is formed on top of the first conductive bump, wherein the second conductive bond formation is a first conductive wedge formed directly on the second conductive bonding surface, and wherein the fourth conductive bond formation is a second conductive wedge formed directly on the second conductive bonding surface.

Aspect 10: The method of any of Aspects 1-9, wherein the first conductive bond formation is formed directly on the first conductive bonding surface, wherein the second conductive bond formation is a first conductive wedge formed directly on the second conductive bonding surface, and wherein the fourth conductive bond formation is a second conductive wedge formed directly on the second conductive bonding surface.

Aspect 11: The method of any of Aspects 1-10, further comprising: forming a first conductive bump on top of the first conductive bonding surface, wherein the first conductive bond formation is formed on top of the first conductive bump; and forming a second conductive bump on top of the second conductive bonding surface, wherein the fourth conductive bond formation is formed on top of the second conductive bump, wherein the conductive structure is a first conductive ball, wherein the first conductive bond formation is a first conductive wedge, wherein the fourth conductive bond formation is a second conductive wedge, wherein the second conductive bond formation is a second conductive ball, and wherein the third conductive bond formation is formed on top of the first conductive ball.

Aspect 12: The method of any of Aspects 1-11, wherein the conductive structure is a conductive bump, wherein the first conductive bond formation is a first conductive wedge formed directly on the first conductive bonding surface, wherein the third conductive bond formation is a second conductive wedge formed directly on the conductive bump, wherein the second conductive bond formation is a first conductive ball formed directly on the second conductive bonding surface, and wherein the fourth conductive bond formation is a second conductive ball formed directly on the second conductive bonding surface.

Aspect 13: The method of any of Aspects 1-12, further comprising: forming a first conductive bump on top of the first conductive bonding surface, wherein the conductive structure is a second conductive bump, wherein the first conductive bond formation is a first conductive wedge formed on top of the first conductive bump, wherein the second conductive bond formation is a conductive ball formed directly on the second conductive bonding surface, wherein the third conductive bond formation is a second conductive wedge formed directly on the second conductive bump, and wherein the fourth conductive bond formation is a third conductive wedge formed directly on the second conductive bonding surface.

Aspect 14: The method of any of Aspects 1-13, wherein the first substrate is a first circuit substrate or a first semiconductor substrate of a first semiconductor chip, and wherein the second substrate is a second circuit substrate or a second semiconductor substrate of a second semiconductor chip.

Aspect 15: A method of forming a wire bond assembly, the method comprising: wire bonding a first end of a first bond wire to a first conductive bonding surface arranged on a first substrate to form a first conductive bond formation; wire bonding a second end of the first bond wire to a second conductive bonding surface arranged on a second substrate to form a second conductive bond formation; forming a first conductive structure on top of the first conductive bond formation; forming a second conductive structure on top of the second conductive bond formation; wire bonding a first end of a second bond wire to a top of the first conductive structure to form a third conductive bond formation; and wire bonding a second end of the second bond wire to a top of the second conductive structure to form a fourth conductive bond formation.

Aspect 16: The method of Aspect 15, wherein the first conductive bond formation, the first conductive structure, and the third conductive bond formation form a first vertical stack on the first conductive bonding surface, and wherein the second conductive bond formation, the second conductive structure, and the fourth conductive bond formation form a second vertical stack on the second conductive bonding surface.

Aspect 17: The method of any of Aspects 15-16, wherein the first bond wire and the second bond wire are coupled to the first conductive bonding surface and the second conductive bonding surface in parallel.

Aspect 18: The method of any of Aspects 15-17, further comprising: forming a first conductive bump on top of the first conductive bonding surface, wherein the first conductive bond formation is formed on top of the first conductive bump; and forming a second conductive bump on top of the second conductive bonding surface, wherein the fourth conductive bond formation is formed on top of the second conductive bump, wherein the first conductive structure is a third conductive bump, wherein the second conductive structure is a fourth conductive bump, and wherein the first conductive bond formation, the second conductive bond formation, the third conductive bond formation, and the fourth conductive bond formation are conductive wedges.

Aspect 19: The method of any of Aspects 15-18, wherein the first conductive bond formation is a first conductive wedge formed directly on the first conductive bonding surface, wherein the second conductive bond formation is a second conductive wedge formed directly on the second conductive bonding surface, wherein the first conductive structure is a first conductive bump, wherein the second conductive structure is a second conductive bump, wherein the third conductive bond formation is a third conductive wedge formed directly on the first conductive bump, and wherein the fourth conductive bond formation is a fourth conductive wedge formed directly on the second conductive bump.

Aspect 20: The method of any of Aspects 15-19, wherein the first conductive bond formation is a first conductive wedge formed directly on the first conductive bonding surface, wherein the second conductive bond formation is a second conductive wedge formed directly on the second conductive bonding surface, wherein the first conductive structure is a first conductive bump, wherein the second conductive structure is a second conductive bump, wherein the third conductive bond formation is a third conductive wedge formed directly on the first conductive bump, and wherein the fourth conductive bond formation is a conductive ball formed directly on the second conductive bump.

Aspect 21: A wire bond assembly, comprising: a first substrate comprising a first conductive bonding surface; a second substrate comprising a second conductive bonding surface; a first conductive bump arranged on the first conductive bonding surface; a first conductive ball arranged on the second conductive bonding surface, wherein the first conductive ball is bonded to a first end of a first bond wire; a second conductive ball arranged on the second conductive bonding surface, wherein the second conductive ball is bonded to a first end of a second bond wire, and wherein the second conductive ball is laterally separated from the first conductive ball on the second conductive bonding surface; and a second conductive bump, wherein a second end of the first bond wire is wire bonded to a top of the first conductive bump to form a first conductive bond formation, wherein the second conductive bump is arranged on the first conductive bond formation, and wherein a second end of the second bond wire is wire bonded to a top of the second conductive bump to form a second conductive bond formation.

Aspect 22: The wire bond assembly of Aspect 21, wherein the first bond wire and the second bond wire are coupled to the first conductive bonding surface and the second conductive bonding surface in a v-configuration to form an electrically parallel connection between the first conductive bonding surface and the second conductive bonding surface.

Aspect 23: The wire bond assembly of any of Aspects 21-22, wherein the first conductive bump, the first conductive bond formation, the second conductive bump, and the second conductive bond formation form a vertical stack on the first conductive bonding surface.

Aspect 24: The wire bond assembly of any of Aspects 21-23, wherein the first conductive bump is directly coupled to the first conductive bonding surface, the first conductive bond formation is directly coupled to the first conductive bump, the second conductive bump is directly coupled to the first conductive bond formation, and the second conductive bond formation is directly coupled to the second conductive bump.

Aspect 25: A system configured to perform one or more operations recited in one or more of Aspects 1-24.

Aspect 26: An apparatus comprising means for performing one or more operations recited in one or more of Aspects 1-24.

Aspect 27: A non-transitory computer-readable medium storing a set of instructions, the set of instructions comprising one or more instructions that, when executed by a device, cause the device to perform one or more operations recited in one or more of Aspects 1-24.

Aspect 28: A computer program product comprising instructions or code for executing one or more operations recited in one or more of Aspects 1-24.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A method of forming a wire bond assembly, the method comprising:
wire bonding a first end of a first bond wire to a first conductive bonding surface arranged on a first substrate to form a first conductive bond formation;
wire bonding a second end of the first bond wire to a second conductive bonding surface arranged on a second substrate to form a second conductive bond formation;
forming a conductive structure on top of the first conductive bond formation;
wire bonding a first end of a second bond wire to a top of the conductive structure to form a third conductive bond formation; and
wire bonding a second end of the second bond wire to the second conductive bonding surface to form a fourth conductive bond formation, wherein the fourth conductive bond formation is laterally separated from the second conductive bond formation on the second conductive bonding surface.

2. The method of claim 1, wherein the first bond wire and the second bond wire are coupled to the first conductive bonding surface and the second conductive bonding surface in a v-configuration to form an electrically parallel connection between the first conductive bonding surface and the second conductive bonding surface.

3. The method of claim 1, wherein the first conductive bond formation, the conductive structure, and the third conductive bond formation form a vertical stack on the first conductive bonding surface.

4. The method of claim 1, wherein the first conductive bond formation is a first conductive wedge,
wherein the second conductive bond formation is a first conductive ball,
wherein the third conductive bond formation is a second conductive wedge, and
wherein the fourth conductive bond formation is a second conductive ball.

5. The method of claim 1, further comprising:
forming a first conductive bump on top of the first conductive bonding surface,
wherein the conductive structure is a second conductive bump, and
wherein the first conductive bond formation is formed on top of the first conductive bump.

6. The method of claim 5, wherein the first conductive bump is formed directly on the first conductive bonding surface, the first conductive bond formation is formed directly on the first conductive bump, the second conductive bump is formed directly on the first conductive bond formation, and the third conductive bond formation is formed directly on the second conductive bump.

7. The method of claim 5, further comprising:
forming a third conductive bump on top of the second conductive bonding surface; and
forming a fourth conductive bump on top of the second conductive bonding surface, wherein the fourth conductive bump is laterally separated from the third conductive bump on the second conductive bonding surface,
wherein the second conductive bond formation is formed on top of the third conductive bump, and
wherein the fourth conductive bond formation is formed on top of the fourth conductive bump.

8. The method of claim 7, wherein the first conductive bond formation is a first conductive wedge,
wherein the second conductive bond formation is a second conductive wedge,
wherein the third conductive bond formation is a third conductive wedge, and
wherein the fourth conductive bond formation is a fourth conductive wedge.

9. The method of claim 1, further comprising:
forming a first conductive bump on top of the first conductive bonding surface,
wherein the conductive structure is a second conductive bump,
wherein the first conductive bond formation is formed on top of the first conductive bump,
wherein the second conductive bond formation is a first conductive wedge formed directly on the second conductive bonding surface, and
wherein the fourth conductive bond formation is a second conductive wedge formed directly on the second conductive bonding surface.

10. The method of claim 1, wherein the first conductive bond formation is formed directly on the first conductive bonding surface,
wherein the second conductive bond formation is a first conductive wedge formed directly on the second conductive bonding surface, and
wherein the fourth conductive bond formation is a second conductive wedge formed directly on the second conductive bonding surface.

11. The method of claim 1, further comprising:
forming a first conductive bump on top of the first conductive bonding surface, wherein the first conductive bond formation is formed on top of the first conductive bump; and
forming a second conductive bump on top of the second conductive bonding surface, wherein the fourth conductive bond formation is formed on top of the second conductive bump,
wherein the conductive structure is a first conductive ball,
wherein the first conductive bond formation is a first conductive wedge,
wherein the fourth conductive bond formation is a second conductive wedge,
wherein the second conductive bond formation is a second conductive ball, and
wherein the third conductive bond formation is formed on top of the first conductive ball.

12. The method of claim 1, wherein the conductive structure is a conductive bump,
wherein the first conductive bond formation is a first conductive wedge formed directly on the first conductive bonding surface,
wherein the third conductive bond formation is a second conductive wedge formed directly on the conductive bump,
wherein the second conductive bond formation is a first conductive ball formed directly on the second conductive bonding surface, and
wherein the fourth conductive bond formation is a second conductive ball formed directly on the second conductive bonding surface.

13. The method of claim 1, further comprising:
forming a first conductive bump on top of the first conductive bonding surface,
wherein the conductive structure is a second conductive bump,
wherein the first conductive bond formation is a first conductive wedge formed on top of the first conductive bump,
wherein the second conductive bond formation is a conductive ball formed directly on the second conductive bonding surface,
wherein the third conductive bond formation is a second conductive wedge formed directly on the second conductive bump, and
wherein the fourth conductive bond formation is a third conductive wedge formed directly on the second conductive bonding surface.

14. The method of claim 1, wherein the first substrate is a first circuit substrate or a first semiconductor substrate of a first semiconductor chip, and
wherein the second substrate is a second circuit substrate or a second semiconductor substrate of a second semiconductor chip.

15. A method of forming a wire bond assembly, the method comprising:
wire bonding a first end of a first bond wire to a first conductive bonding surface arranged on a first substrate to form a first conductive bond formation;
wire bonding a second end of the first bond wire to a second conductive bonding surface arranged on a second substrate to form a second conductive bond formation;
forming a first conductive structure on top of the first conductive bond formation;
forming a second conductive structure on top of the second conductive bond formation;
wire bonding a first end of a second bond wire to a top of the first conductive structure to form a third conductive bond formation; and
wire bonding a second end of the second bond wire to a top of the second conductive structure to form a fourth conductive bond formation.

16. The method of claim 15, wherein the first conductive bond formation, the first conductive structure, and the third conductive bond formation form a first vertical stack on the first conductive bonding surface, and
wherein the second conductive bond formation, the second conductive structure, and the fourth conductive bond formation form a second vertical stack on the second conductive bonding surface.

17. The method of claim 15, wherein the first bond wire and the second bond wire are coupled to the first conductive bonding surface and the second conductive bonding surface in parallel.

18. The method of claim 15, further comprising:
forming a first conductive bump on top of the first conductive bonding surface, wherein the first conductive bond formation is formed on top of the first conductive bump; and
forming a second conductive bump on top of the second conductive bonding surface, wherein the fourth conductive bond formation is formed on top of the second conductive bump,
wherein the first conductive structure is a third conductive bump,
wherein the second conductive structure is a fourth conductive bump, and
wherein the first conductive bond formation, the second conductive bond formation, the third conductive bond formation, and the fourth conductive bond formation are conductive wedges.

19. The method of claim 15, wherein the first conductive bond formation is a first conductive wedge formed directly on the first conductive bonding surface,
wherein the second conductive bond formation is a second conductive wedge formed directly on the second conductive bonding surface,
wherein the first conductive structure is a first conductive bump,
wherein the second conductive structure is a second conductive bump,
wherein the third conductive bond formation is a third conductive wedge formed directly on the first conductive bump, and
wherein the fourth conductive bond formation is a fourth conductive wedge formed directly on the second conductive bump.

20. The method of claim 15, wherein the first conductive bond formation is a first conductive wedge formed directly on the first conductive bonding surface,
wherein the second conductive bond formation is a second conductive wedge formed directly on the second conductive bonding surface,
wherein the first conductive structure is a first conductive bump,
wherein the second conductive structure is a second conductive bump,
wherein the third conductive bond formation is a third conductive wedge formed directly on the first conductive bump, and
wherein the fourth conductive bond formation is a conductive ball formed directly on the second conductive bump.

21. A wire bond assembly, comprising:
a first substrate comprising a first conductive bonding surface;
a second substrate comprising a second conductive bonding surface;
a first conductive bump arranged on the first conductive bonding surface;
a first conductive ball arranged on the second conductive bonding surface, wherein the first conductive ball is bonded to a first end of a first bond wire;
a second conductive ball arranged on the second conductive bonding surface, wherein the second conductive ball is bonded to a first end of a second bond wire, and wherein the second conductive ball is laterally separated from the first conductive ball on the second conductive bonding surface; and
a second conductive bump,
wherein a second end of the first bond wire is wire bonded to a top of the first conductive bump to form a first conductive bond formation,
wherein the second conductive bump is arranged on the first conductive bond formation, and
wherein a second end of the second bond wire is wire bonded to a top of the second conductive bump to form a second conductive bond formation.

22. The wire bond assembly of claim 21, wherein the first bond wire and the second bond wire are coupled to the first conductive bonding surface and the second conductive bonding surface in a v-configuration to form an electrically parallel connection between the first conductive bonding surface and the second conductive bonding surface.

23. The wire bond assembly of claim 21, wherein the first conductive bump, the first conductive bond formation, the second conductive bump, and the second conductive bond formation form a vertical stack on the first conductive bonding surface.

24. The wire bond assembly of claim 21, wherein the first conductive bump is directly coupled to the first conductive bonding surface, the first conductive bond formation is directly coupled to the first conductive bump, the second conductive bump is directly coupled to the first conductive bond formation, and the second conductive bond formation is directly coupled to the second conductive bump.
